(19) United States
(12) Patent Application Publication
(10) Pub. No.: US 2025/0309857 A1
(43) Pub. Date: Oct. 2, 2025

(54) PHASE SHIFTING CIRCUIT

(71) Applicant: Murata Manufacturing Co., Ltd., Kyoto (JP)

(72) Inventor: Masatoshi Hase, Kyoto (JP)

(21) Appl. No.: 19/089,786

(22) Filed: Mar. 25, 2025

(30) Foreign Application Priority Data
Mar. 29, 2024 (JP) 2024-056639

(51) Int. Cl. H03H 7/20; H03H 7/01; H03H 7/42

(52) U.S. Cl. CPC H03H 7/20; H03H 7/0115; H03H 7/42

(57) ABSTRACT

A phase shifting circuit includes a dividing circuit that divides an input signal into a first signal and a second signal, the second signal having a phase different from a phase of the first signal; a first phase shifter that shifts the phase of the first signal by a first angle and outputs a first output signal; a second phase shifter that shifts the phase of the second signal by a second angle in a direction opposite to a direction of the first angle and outputs a second output signal, the second output signal having a phase difference that is greater than 0 degrees and less than 90 degrees relative to the first output signal; a first amplifier that amplifies the first output signal and outputs a first amplified signal; and a second amplifier that amplifies the second output signal and outputs a second amplified signal.

### CROSS REFERENCE TO RELATED APPLICATION

This application claims priority from Japanese Patent Application No. 2024-056639, filed on Mar. 29, 2024. The content of this application is incorporated herein by reference in its entirety.

### BACKGROUND OF THE DISCLOSURE

### 1. Field of the Disclosure

The present disclosure relates to a phase shifting circuit.

### 2. Description of the Related Art

Digital modulation systems are widely used in various multi-carrier (multiple carrier waves) communication systems, such as wireless and satellite communications, to enhance communication capacity and achieve high data communication speeds. Information to be transmitted in a digital modulation system is incorporated in both the amplitude and phase of a signal and is transmitted after modulation. Japanese Unexamined Patent Application Publication No. 2012-120037 (Patent Document 1) discloses an electronic circuit that corrects signal distortion, which can degrade signal quality when such a signal is transmitted. This electronic circuit includes a phase difference divider that shifts the phase of an input signal.

### BRIEF SUMMARY OF THE DISCLOSURE

The phase difference divider included in the electronic circuit described in Patent Document 1 includes a 90-degree hybrid coupler that receives and divides an input signal, and a phase shifting circuit. The phase shifting circuit includes a first line, a second line, and a resistor. One end of the first line is electrically connected to one end of the 90-degree hybrid coupler. One end of the second line is electrically connected to the other end of the 90-degree hybrid coupler. Further, one end of the resistor is electrically connected to the other end of the first line, and the other end of the resistor is electrically connected to the other end of the second line. That is to say, the phase difference divider is configured such that the resistor is electrically connected between the one end, which serves as an in-phase output terminal of the 90-degree hybrid coupler, and the other end, which serves as an output terminal of the 90-degree hybrid coupler with a phase difference of 90 degrees. This enables the phase difference divider to output a signal having a desired phase difference relative to the input signal.

However, in the phase difference divider included in the electronic circuit described in Patent Document 1, a first signal flowing into the second line from the first line via the resistor and a second signal flowing into the first line from the second line via the resistor in a direction opposite to that of the first signal, cancel each other out. This causes power loss.

The present disclosure is made in view of such circumstances, and a possible benefit thereof is to provide a phase shifting circuit capable of reducing loss.

To achieve this possible benefit, a phase shifting circuit according to one aspect of the present disclosure includes: a dividing circuit that divides an input signal into a first signal and a second signal, the second signal having a phase different from a phase of the first signal; a first phase shifter that shifts the phase of the first signal by a first angle and outputs a first output signal; a second phase shifter that shifts the phase of the second signal by a second angle in a direction opposite to a direction of the first angle and outputs a second output signal, the second output signal having a phase difference that is greater than 0 degrees and less than 90 degrees relative to the first output signal; a first amplifier that amplifies the first output signal and outputs a first amplified signal; and a second amplifier that amplifies the second output signal and outputs a second amplified signal, the second amplifier being connected to the first amplifier such that the first amplified signal and the second amplified signal are combined.

According to the present disclosure, it becomes possible to provide a phase shifting circuit capable of reducing loss.

### BRIEF DESCRIPTION OF THE SEVERAL VIEWS OF THE DRAWINGS

FIG. 1 is a diagram illustrating one example of a configuration of a power amplifying circuit;

FIGS. 2A and 2B are diagrams illustrating one example of an overview of a configuration of a phase shifting circuit;

FIG. 3 is a diagram illustrating one example of a specific configuration of the phase shifting circuit;

FIG. 4 is a graph illustrating a relationship between the signal loss in the phase shifting circuit and the phase difference;

FIG. 5 is a diagram illustrating a configuration of part of a phase shifting circuit according to a first modification;

FIG. 6 is a diagram illustrating a configuration of part of a phase shifting circuit according to a second modification;

FIG. 7 is a diagram illustrating a configuration of part of a phase shifting circuit according to a third modification; and

FIGS. 8A and 8B are diagrams illustrating exemplary configurations of a first phase shifter and a second phase shifter according to a modification.

### DETAILED DESCRIPTION OF THE DISCLOSURE

Hereinafter, embodiments of the present disclosure will be described in detail with reference to the drawings. Note that identical reference characters denote identical constituent elements, and overlapping descriptions are omitted.

===Power Amplifying Circuit 10===

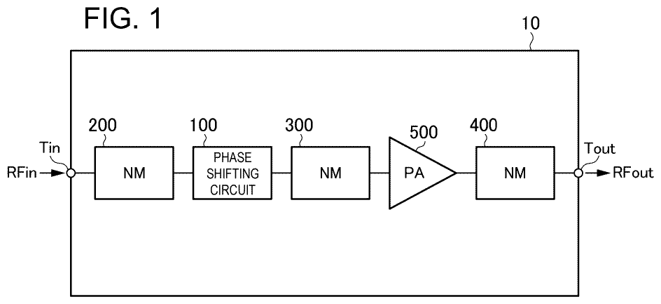

Referring to FIG. 1, a power amplifying circuit 10 is described. FIG. 1 is a diagram illustrating one example of a configuration of the power amplifying circuit 10. The power amplifying circuit 10 illustrated in FIG. 1 is, for example, mounted on a mobile communication device such as a mobile phone or the like, and is used to amplify the power of a radio frequency (RF) signal to be transmitted to a base station.

The power amplifying circuit 10 amplifies the power of signals for communication standards such as, for example, second-generation mobile communication system (2G), third-generation mobile communication system (3G), fourth-generation mobile communication system (4G), fifth-generation mobile communication system (5G), Long Term Evolution Frequency Division Duplex (LTE-FDD), LTE Time Division Duplex (LTE-TDD), LTE-Advanced, LTE-Advanced Pro, sixth-generation mobile communication system (6G), or the like. Further, frequencies of the RF signals range, for example, from around several hundred MHz to around 100 GHz. Note that the communication standards and frequencies of the signals to be amplified by the power amplifying circuit 10 are not limited to the ones described above.

The power amplifying circuit 10 includes, for example, a phase shifting circuit 100, an input matching circuit 200, an intermediate matching circuit 300, an output matching circuit 400, and an output amplifying circuit 500.

The phase shifting circuit 100 is a circuit that outputs a signal formed by shifting the phase of an input signal RFin to a predetermined angle. The phase shifting circuit 100 will be described below in detail.

The input matching circuit 200 is, for example, a circuit that precedes the phase shifting circuit 100 and provides impedance matching between an input terminal Tin and the phase shifting circuit 100.

The intermediate matching circuit 300 is a circuit that follows the phase shifting circuit 100 and provides impedance matching between the phase shifting circuit 100 and the output amplifying circuit 500.

The output matching circuit 400 is a circuit that follows the output amplifying circuit 500 and provides impedance matching between the output amplifying circuit 500 and a circuit (not illustrated) that follows an output terminal Tout.

The output amplifying circuit 500 outputs an output signal RFout, which is formed by amplifying a signal outputted from the phase shifting circuit 100, to the output terminal Tout via the output matching circuit 400.

The phase shifting circuit 100 and the output amplifying circuit 500 are each configured, for example, to incorporate a bipolar transistor such as a heterojunction bipolar transistor (HBT) or the like. Note that, instead of using the HBT, the phase shifting circuit 100 and the output amplifying circuit 500 may each be configured to incorporate a metal-oxide-semiconductor field-effect transistor (MOSFET).

The power amplifying circuit 10 can output the output signal RFout, which is formed by performing phase shifting such that the output signal RFout has a desired phase relative to the input signal RFin, to an antenna, while reducing signal loss caused by the phase shifting circuit 100.

Note that in the description referring to FIG. 1, it is considered that the phase shifting circuit 100 is integrated into the power amplifying circuit 10, which includes the single-stage output amplifying circuit 500. However, the present disclosure is not limited thereto, and, for example, the power amplifying circuit 10 may be a power amplifying circuit incorporating a multi-stage amplifying circuit, a differential amplifying circuit, or a Doherty amplifying circuit.

### ===Phase Shifting Circuit 100===

### <<Overview of Configuration>>

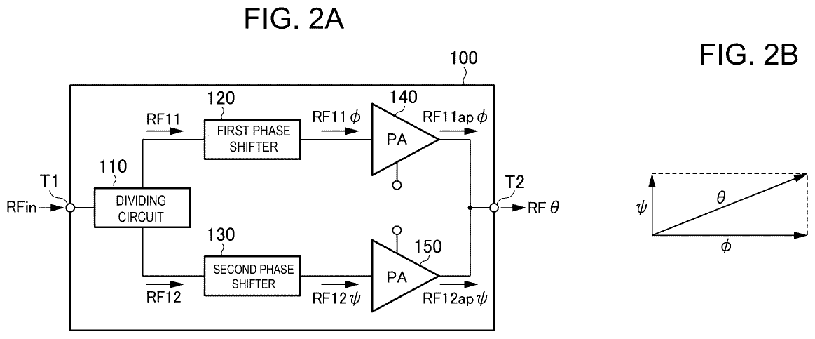

Referring to FIGS. 2A and 2B, one example of the configuration of the phase shifting circuit 100 is described. FIGS. 2A and 2B are diagrams illustrating one example of an overview of the configuration of the phase shifting circuit 100.

As illustrated in FIG. 2A, the phase shifting circuit 100 includes, for example, a dividing circuit 110, a first phase shifter 120, a second phase shifter 130, a first amplifier 140, and a second amplifier 150.

The phase shifting circuit 100 outputs a signal with a desired phase by combining two signals obtained in the dividing circuit 110, where the input signal RFin is divided into two signals having a phase difference that is greater than 0 degrees and less than 90 degrees.

The dividing circuit 110 is a circuit that divides the input signal RFin into a signal RF11 (first signal) and a signal RF12 (second signal) with a phase different from that of the signal RF11. The dividing circuit 110 may be, for example, a 90-degree hybrid circuit or a circuit that includes a balun, a Wilkinson type divider, a web-type divider, or the like.

The first phase shifter 120 is a circuit that shifts the phase of the signal RF11 by a first angle and outputs a first output signal (hereinafter, referred to as “signal RFϕ”). In FIG. 2A, “o” represents the phase of the signal RFϕ outputted from the first phase shifter 120.

The second phase shifter 130 is a circuit that shifts the phase of the signal RF12 by a second angle in the direction opposite to the direction of the first angle and outputs a second output signal (hereinafter, referred to as “signal RFψ”) having a phase difference that is greater than 0 degrees and less than 90 degrees relative to the signal RFϕ. In FIG. 2A, “ψ” represents the phase of the signal RF outputted from the second phase shifter 130.

The second angle may be, for example, an angle that has an absolute value equal to that of the first angle and is in the direction opposite to the direction of the first angle. Specifically, for example, in the case where the first phase shifter 120 shifts the phase of the signal RF11 by 67.5 degrees (first angle) in the lagging direction, the second phase shifter 130 may be configured to shift the phase of the signal RF12 by 67.5 degrees (second angle) in the leading direction opposite to the lagging direction. This facilitates the design of the phase shifting circuit 100.

The phase difference being greater than 0 degrees and less than 90 degrees means that when one of the signal RFϕ and the signal RFψ is taken as the reference, the other signal's phase deviates by an angle that is greater than 0 degrees and less than 90 degrees in one of the leading direction and the lagging direction. Specifically, in the case where the phase of the signal RFϕ is 67.5 degrees in the lagging direction and the phase of the signal RFψ is 22.5 degrees in the lagging direction, the signal RFψ has a phase difference of 45.0 degrees in the leading direction when the signal RFϕ is taken as the reference, and thus the phase difference is greater than 0 degrees and less than 90 degrees. Further, in the case where the phase of the signal RFϕ is 112.5 degrees in the leading direction and the phase of the signal RFψ is 202.5 degrees in the lagging direction, the signal RFψ has a phase difference of 315.0 degrees in the lagging direction when the signal RFϕ is taken as the reference. In other words, since the signal completes one cycle in 360 degrees, it can be said that the signal RFψ has a phase difference of 45.0 degrees in the leading direction when the signal RFϕ is taken as the reference, and thus the phase difference is greater than 0 degrees and less than 90 degrees.

The first amplifier 140 outputs a first amplified signal (hereinafter, referred to as “amplified signal RFapϕ”) that is formed by amplifying a signal RF11ϕ outputted from the first phase shifter 120. The output of the first amplifier 140 is electrically connected to an output terminal T2. The first amplifier 140 receives a bias from a bias circuit that is not illustrated. The first amplifier 140 includes a transistor. For example, the signal RF11ϕ is inputted to the base of this transistor via a capacitor. Further, the collector of the transistor is electrically connected to the output terminal T2, and the emitter of the transistor is electrically connected to a reference potential via a resistor.

The second amplifier 150 outputs a second amplified signal (hereinafter, referred to as “amplified signal RFapψ”) that is formed by amplifying a signal RF12 outputted from the second phase shifter 130. The output of the second amplifier 150 is electrically connected to the output terminal T2. The second amplifier 150 receives a bias from a bias circuit that is not illustrated. The second amplifier 150 includes a transistor. For example, the signal RF12ψ is inputted to the base of this transistor via a capacitor. Further, the collector of the transistor is electrically connected to the output terminal T2, and the emitter of the transistor is electrically connected to the reference potential via a resistor.

That is to say, the output of the first amplifier 140 is electrically connected to the output of the second amplifier 150. Specifically, the output of the first amplifier 140 may be directly electrically connected to the output of the second amplifier 150 or may be electrically connected via a combiner (for example, a balun or the like) that combines signals. Note that by directly electrically connecting the output of the first amplifier 140 to the output of the second amplifier 150, the phase shifting circuit 100 can avoid an occurrence of loss caused by the combiner.

As illustrated in FIG. 2B, the phase shifting circuit 100 outputs a signal with a phase, which is represented by a vector θ (hereinafter, referred to as “combined signal RFθ”). A vector ¢ is a vector representing the amplified signal RFapϕ outputted from the first amplifier 140. The length of the vector represents the magnitude of the signal, and the direction of the vector represents the phase of the signal. Similarly, a vector ψ is a vector representing the amplified signal RFapψ outputted from the second amplifier 150.

As described above, by shifting the phase of the input signal RFin using the dividing circuit 110, the first phase shifter 120, and the second phase shifter 130 included in the phase shifting circuit 100, the power amplifying circuit 10 can output an amplified signal with a desired phase from the output amplifying circuit 500.

### <<Details of Configuration>>

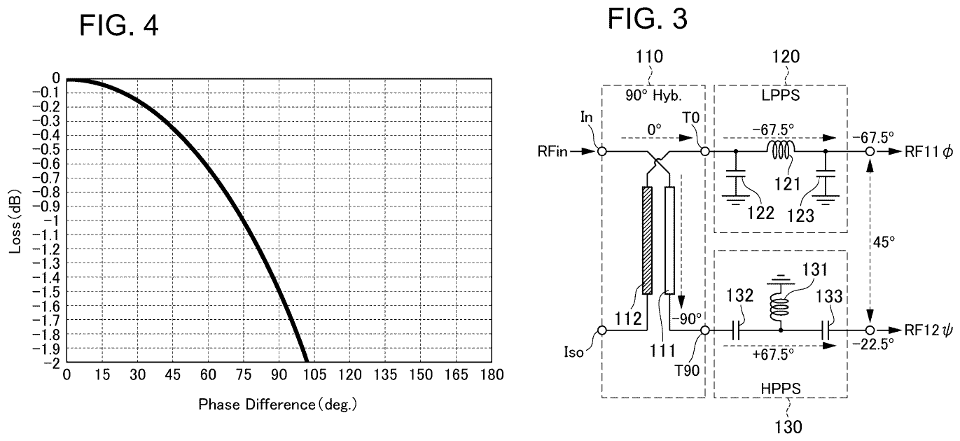

Next, referring to FIG. 3 and FIG. 4, a detailed configuration of the phase shifting circuit 100 is described. FIG. 3 is a diagram illustrating one example of the detailed configuration of the phase shifting circuit 100. FIG. 4 is a graph illustrating a relationship between the signal loss in the phase shifting circuit 100 and the phase difference. In FIG. 4, the vertical axis represents the signal loss (dB), and the horizontal axis represents the phase difference (deg) between the signal RF11ϕ and the signal RF12ψ.

For example, the dividing circuit 110 is a 90-degree hybrid circuit and divides the input signal RFin into two signals with a phase difference of 90 degrees. The term “90 degrees” refers to an angle that is approximately 90 degrees, and includes, for example, angles from 70 degrees to 110 degrees. The dividing circuit 110 includes coupling lines 111 and 112 that form electromagnetic coupling with a ¼ wavelength, a terminal In, a terminal Iso, a terminal T0, and a terminal T90. The input signal RFin is inputted to the terminal In. The terminal Iso is connected to, for example, a load (for example, a load of 502) whose magnitude is equal to the characteristic impedance of a transmission line. From the terminal TO, a signal RF11 is outputted, which is at −3 dB and in the same phase with the input signal RFin. From the terminal T90, a signal RF12 is outputted, which is at −3 dB and lags the input signal RFin by 90 degrees in phase.

The first phase shifter 120 is, for example, an n-type low pass filter circuit, and is a circuit that delays the phase of the signal RF11 (for example, in phase with the input signal RFin) inputted via the terminal TO.

Specifically, for example, the first phase shifter 120 includes an inductor 121 (first inductor), a capacitor 122 (first capacitor), and a capacitor 123 (second capacitor). The inductor 121 is connected in series to the terminal TO of the dividing circuit 110. One end of the capacitor 122 is electrically connected to a node between the terminal TO and one end of the inductor 121, and the other end of the capacitor 122 is electrically connected to the reference potential. One end of the capacitor 123 is electrically connected to the other end of the inductor 121, and the other end of the capacitor 123 is electrically connected to the reference potential. As described above, the first phase shifter 120 is configured to incorporate only one inductor, and thus, it becomes possible to reduce the size of the power amplifying circuit 10.

According to this configuration, the first phase shifter 120 outputs the signal RF11ϕ, which is formed by shifting the phase of the signal RF11 inputted via the terminal TO in the lagging direction (−67.5 degrees in FIG. 3), to the first amplifier 140. Note that in the first phase shifter 120, the phase angle in the lagging direction is determined by the respective parameters of the inductor 121, the capacitor 122, and the capacitor 123.

The second phase shifter 130 is, for example, a T-type high pass filter circuit, and is a circuit that advances the phase (for example, the phase that lags the phase of the input signal RFin by 90 degrees) of the signal RF12 inputted via the terminal T90.

Specifically, for example, the second phase shifter 130 includes an inductor 131 (second inductor), a capacitor 132 (third capacitor), and a capacitor 133 (fourth capacitor). The capacitor 132 is connected in series to the terminal T90 of the dividing circuit 110. The capacitor 133 is connected in series to the capacitor 132. One end of the inductor 131 is electrically connected to a node between the capacitor 132 and the capacitor 133, and the other end of the inductor 131 is electrically connected to the reference potential. As described above, the second phase shifter 130 is configured to incorporate only one inductor, and thus, it becomes possible to reduce the size of the power amplifying circuit 10.

According to this configuration, the second phase shifter 130 outputs the signal RF12ψ, which is formed by shifting the phase of the signal RF12 inputted via the terminal T90 in the leading direction (+67.5 degrees in FIG. 3), to the second amplifier 150. Note that in the second phase shifter 130, the phase angle in the leading direction is determined by the respective parameters of the inductor 131, the capacitor 132, and the capacitor 133.

Because of this, the phase shifting circuit 100 realizes phase shifting using a smaller number of inductors while reducing loss. This enables the reduction in size of the phase shifting circuit 100.

As described above, the phase shifting circuit 100 generates two signals, the signal RF11ϕ and the signal RF12ψ, which have a phase difference that is greater than 0 degrees and less than 90 degrees. Further, the combined signal RFθ, which is formed by combing the amplified signal RFapϕ and the amplified signal RFapψ, is outputted from the output terminal T2 of the phase shifting circuit 100. The combined signal RFθ (in FIG. 3, the phase 0 is “22.5 degrees”) is a signal formed by combining two signals having a phase difference that is greater than 0 degrees and less than 90 degrees (for example, a phase difference of 45 degrees).

As illustrated in FIG. 4, in the phase shifting circuit 100, the signal loss relating to signal combining decreases when the phase difference is less than 90 degrees. Thus, it is desirable to configure the phase shifting circuit 100 such that two signals having a phase difference that is greater than 0 degrees and less than 90 degrees are combined. In addition, as illustrated in FIG. 4, the signal loss increases when the phase difference exceeds 45 degrees. Thus, it is desirable to configure the phase shifting circuit 100 such that the phase difference between the two signals to be combined is approximately 45 degrees.

### <<First Modification>>

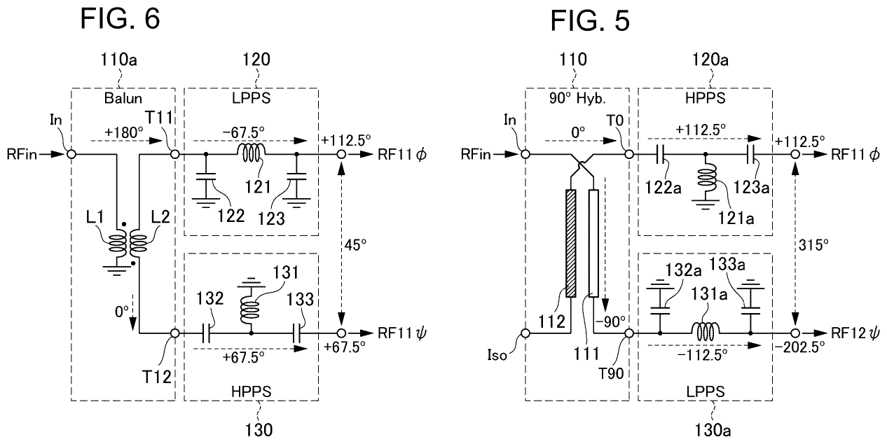

Next, referring to FIG. 5, a first modification of the configuration of the phase shifting circuit 100 is described. FIG. 5 is a diagram illustrating a configuration of part of a phase shifting circuit 100a according to the first modification. Unless otherwise described below, the configuration is identical to that of the phase shifting circuit 100.

The phase shifting circuit 100a is a circuit formed by replacing the first phase shifter 120 of the phase shifting circuit 100 with a first phase shifter 120a and replacing the second phase shifter 130 of the phase shifting circuit 100 with a second phase shifter 130a.

The first phase shifter 120a is, for example, a T-type high pass filter circuit, and is a circuit that advances the phase of the signal RF11 (for example, in phase with the input signal RFin) inputted via the terminal TO.

Specifically, for example, the first phase shifter 120a includes an inductor 121a (third inductor), a capacitor 122a (fifth capacitor), and a capacitor 123a (sixth capacitor). The capacitor 122a is connected in series to the terminal TO of the dividing circuit 110. The capacitor 123a is connected in series to the capacitor 122a. One end of the inductor 121a is electrically connected to a node between the capacitor 122a and the capacitor 123a, and the other end of the inductor 121a is electrically connected to the reference potential.

According to this configuration, the first phase shifter 120a outputs the signal RF11ϕ, which is formed by shifting the phase of the signal RF11 that is in the same phase with the input signal RFin outputted from the terminal TO in the leading direction (+112.5 degrees in FIG. 5), to the first amplifier 140.

The second phase shifter 130a is, for example, an n-type low pass filter circuit, and is a circuit that delays the phase of the signal RF12 (for example, the phase that lags the phase of the input signal RFin by 90 degrees) inputted via the terminal T90.

Specifically, for example, the second phase shifter 130a includes an inductor 131a (fourth inductor), a capacitor 132a (seventh capacitor), and a capacitor 133a (eighth capacitor). The inductor 131a is connected in series to the terminal T90 of the dividing circuit 110. One end of the capacitor 132a is electrically connected to a node between the terminal T90 and one end of the inductor 131a, and the other end of the capacitor 132a is electrically connected to the reference potential. One end of the capacitor 133a is electrically connected to the other end of the inductor 131a, and the other end of the capacitor 133a is electrically connected to the reference potential.

According to this configuration, the second phase shifter 130a outputs the signal RF12ψ that is formed by shifting the phase of the signal RF12, which lags the phase of the input signal RFin outputted from the terminal T90 by 90 degrees in the lagging direction (−112.5 degrees in FIG. 5), to the second amplifier 150.

Because of the above configuration, the combined signal RFθ is outputted from the output terminal T2 of the phase shifting circuit 100a. The combined signal RFθ (the phase 0 is “22.5 degrees”) is a signal formed by combining an amplified signal RFllapϕ and an amplified signal RFap12ψ, which are two signals having a phase difference that is greater than 0 degrees and less than 90 degrees (the phase difference is 315 degrees in FIG. 5, and this is equal to a phase difference of 45 degrees).

Because of this, the phase shifting circuit 100a realizes phase shifting using a smaller number of inductors while reducing loss. This enables the reduction in size of the phase shifting circuit 100a.

### <<Second Modification>>

Next, referring to FIG. 6, a second modification of the configuration of the phase shifting circuit 100 is described. FIG. 6 is a diagram illustrating a configuration of part of a phase shifting circuit 100b according to the second modification. Unless otherwise described below, the configuration is identical to that of the phase shifting circuit 100.

The phase shifting circuit 100b is a circuit formed by replacing the dividing circuit 110 of the phase shifting circuit 100 with a dividing circuit 110a.

For example, the dividing circuit 110a is a balun and divides the input signal RFin into two signals with a phase difference of 180 degrees. The term “180 degrees” refers to an angle that is approximately 180 degrees and includes, for example, angles from 145 degrees to 225 degrees. The balun is a coupling transformer that converts an unbalanced transmission line L1 to a balanced transmission line L2. The unbalanced transmission line L1 is a line that is formed in a spiral shape and transmits a change in potential relative to the reference potential. The balanced transmission line L2 is a line that is formed in a spiral shape and transmits a pair of signals that are equal in amplitude and differ from each other by 180 degrees in phase. The dividing circuit 110a is configured such that the unbalanced transmission line L1 and the balanced transmission line L2 are electromagnetically coupled to each other with reverse polarity.

In the dividing circuit 110a, a signal RF11, which is at −3 dB and leads the input signal RFin by 180 degrees in phase, is outputted from a terminal T11 to the first phase shifter 120. From a terminal T12, a signal RF12, which is at −3 dB and in phase with the input signal RFin, is outputted to the second phase shifter 130.

Because of this, the phase shifting circuit 100b realizes phase shifting using a smaller number of inductors while reducing loss. This enables the reduction in size of the phase shifting circuit 100b.

### <<Third Modification>>

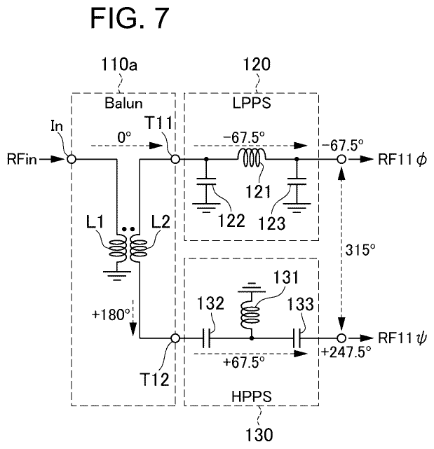

Next, referring to FIG. 7, a third modification of the configuration of the phase shifting circuit 100 is described. FIG. 7 is a diagram illustrating a configuration of part of a phase shifting circuit 100c according to the third modification. Unless otherwise described below, the configuration is identical to that of the phase shifting circuit 100b.

The phase shifting circuit 100c is a circuit formed by replacing the dividing circuit 110a of the phase shifting circuit 100b with a dividing circuit 110b. The dividing circuit 110b is configured such that the unbalanced transmission line L1 and the balanced transmission line L2 are electromagnetically couple to each other with the same polarity.

In the dividing circuit 110b, a signal RF11, which is at −3 dB and in phase with the input signal RFin, is outputted from the terminal T11 to the first phase shifter 120. From the terminal T12, a signal RF12, which is at −3 dB and leads the input signal RFin by 180 degrees in phase, is outputted to the second phase shifter 130.

Because of this, the phase shifting circuit 100c realizes phase shifting using a smaller number of inductors while reducing loss. This enables the reduction in size of the phase shifting circuit 100c.

### <<Fourth Modification>>

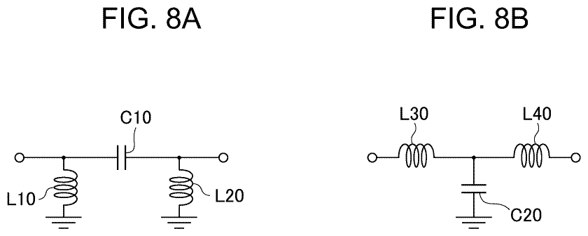

Next, referring to FIGS. 8A and 8B, modifications of the first phase shifter 120 and the second phase shifter 130 are described. FIGS. 8A and 8B are diagrams illustrating exemplary configurations of the first phase shifter 120 and the second phase shifter 130 according to the modifications.

In the section described above, it is described that the first phase shifter 120 and the second phase shifter 130 of the power amplifying circuit 10 are each made up of one inductor and two capacitors. However, the configuration is not limited thereto. Each of the first phase shifter 120 and the second phase shifter 130 only needs to include at least one inductor and at least one capacitor.

Specifically, in the case where the first phase shifter 120 and the second phase shifter 130 are high pass filter circuits, as illustrated in FIG. 8A, the first phase shifter 120 and the second phase shifter 130 may each be made up of two inductors and one capacitor. In this case, a capacitor C10 is connected in series to a terminal (for example, the terminal TO) of the dividing circuit 110. One end of an inductor L10 is electrically connected to a node between the terminal TO and one end of the capacitor C10, and the other end of the inductor L10 is electrically connected to the reference potential. One end of an inductor L20 is electrically connected to the other end of the capacitor C10, and the other end of the inductor L20 is electrically connected to the reference potential.

Further, in the case where the first phase shifter 120 and the second phase shifter 130 are low pass filter circuits, as illustrated in FIG. 8B, the first phase shifter 120 and the second phase shifter 130 may each be made up of two inductors and one capacitor. In this case, an inductor L30 is connected in series to a terminal (for example, the terminal T90) of the dividing circuit 110. An inductor L40 is connected in series to the inductor L30. One end of a capacitor C20 is electrically connected to a node between the inductor L30 and the inductor L40, and the other end of the capacitor C20 is electrically connected to the reference potential.

### <<Operations of Phase Shifting Circuit 100>>

Next, referring to FIG. 1, FIGS. 2A and 2B, and FIG. 3, one example of the operations of the power amplifying circuit 10 including the phase shifting circuit 100 is described.

As illustrated in FIG. 1, an input signal RFin is inputted to the input terminal Tin of the power amplifying circuit 10. The input signal RFin is inputted to the phase shifting circuit 100 via the input matching circuit 200.

As illustrated in FIGS. 2A and 2B, using the dividing circuit 110, the phase shifting circuit 100 divides the input signal RFin into a signal RF11 that is in the same phase with the input signal RFin and a signal RF12 that lags the input signal RFin by 90 degrees in phase. The signal RF11 is inputted to the first phase shifter 120. The signal RF12 is inputted to the second phase shifter 130.

As illustrated in FIG. 3, the first phase shifter 120 outputs a signal RF11ϕ, which is formed by delaying the phase of the signal RF11 by 67.5 degrees, to the first amplifier 140.

Further, the second phase shifter 130 outputs a signal RF12ψ, which is formed by advancing the phase of the signal RF12 by 67.5 degrees, to the second amplifier 150.

The first amplifier 140 outputs an amplified signal RFapϕ, which is formed by amplifying the signal RF11ϕ that lags the input signal RFin by 67.5 degrees in phase, to the terminal T2.

The second amplifier 150 outputs an amplified signal RFapψ, which is formed by amplifying the signal RF12ψ that lags the input signal RFin by 22.5 degrees in phase, to the terminal T2.

Further, the phase shifting circuit 100 outputs, from the terminal T2, a combined signal RFθ that lags the input signal RFin by 22.5 degrees in phase and is formed by combing the amplified signal RFapϕ and the amplified signal RFapψ.

As illustrated in FIG. 1, the combined signal RFθ is inputted to the output amplifying circuit 500 via the intermediate matching circuit 300. The output amplifying circuit 500 outputs an output signal RFout, which is formed by amplifying the combined signal RFθ, from the output terminal Tout to an antenna (not illustrated).

This enables the power amplifying circuit 10 to output an output signal with a desired phase to the antenna using a circuit reduced in size with reduced power loss.

===Conclusion===

<1> The phase shifting circuit 100 according to an exemplary embodiment of the present disclosure includes: the dividing circuit 110 that divides the input signal RFin into the signal RF11 (first signal) and the signal RF12 (second signal), the signal RF12 (second signal) having a phase different from the phase of the signal RF11 (first signal); the first phase shifter 120 that shifts the phase of the signal RF11 (first signal) by a first angle and outputs the signal RFϕ (first output signal); the second phase shifter 130 that shifts the phase of the signal RF12 (second signal) by a second angle in a direction opposite to a direction of the first angle and outputs the signal RFψ (second output signal), the signal RFψ (second output signal) having a phase difference that is greater than 0 degrees and less than 90 degrees relative to the signal RFϕ (first output signal); the first amplifier 140 that amplifies the signal RFϕ (first output signal) and outputs the amplified signal RFapϕ (first amplified signal); and the second amplifier 150 that amplifies the signal RFψ (second output signal) and outputs the amplified signal RFapψ(second amplified signal), the second amplifier 150 being connected to the first amplifier 140 such that the amplified signal RFapϕ (first amplified signal) and the amplified signal RFapψ (second amplified signal) are combined. This enables the phase shifting circuit 100 to reduce the loss relating to the phase shifting.

<2> In the phase shifting circuit according to <1>, the first phase shifter 120 of the phase shifting circuit 100 according to an exemplary embodiment of the present disclosure includes the first inductor (for example, the inductor 121 of FIG. 3, FIG. 6, or FIG. 7) connected in series to the dividing circuit 110, the first capacitor (for example, the capacitor 122 of FIG. 3, FIG. 6, or FIG. 7) electrically connected to one end of the first inductor at one end thereof, another end of the first capacitor being electrically connected to the reference potential, and the second capacitor (for example, the capacitor 123 of FIG. 3, FIG. 6, or FIG. 7) electrically connected to another end of the first inductor at one end thereof, another end of the second capacitor being electrically connected to the reference potential, and the second phase shifter 130 includes the third capacitor (for example, the capacitor 132 of FIG. 3, FIG. 6, or FIG. 7) connected in series to the dividing circuit 110, the fourth capacitor (for example, the capacitor 133 of FIG. 3, FIG. 6, or FIG. 7) connected in series to the third capacitor, and the second inductor (for example, the inductor 131 of FIG. 3, FIG. 6, or FIG. 7) electrically connected to the node between the third capacitor and the fourth capacitor at one end thereof, another end of the second inductor being electrically connected to the reference potential. Because of this, the phase shifting circuit 100 realizes phase shifting using a smaller number of inductors while reducing the loss relating to the phase shifting. This enables the reduction in size of the phase shifting circuit 100.

<3> In the phase shifting circuit according to <1>, the first phase shifter 120a of the phase shifting circuit 100 according to an exemplary embodiment of the present disclosure includes the capacitor 122a (fifth capacitor) connected in series to the dividing circuit 110, the capacitor 123a (sixth capacitor) connected in series to the capacitor 122a, and the inductor 121a (third inductor) electrically connected to the node between the capacitor 122a and the capacitor 123a at one end thereof, another end of the inductor 121a (third inductor) being electrically connected to the reference potential, and the second phase shifter 130a includes the inductor 131a (fourth inductor) connected in series to the dividing circuit 110, the capacitor 132a (seventh capacitor) electrically connected to one end of the inductor 131a at one end thereof, another end of the capacitor 132a (seventh capacitor) being electrically connected to the reference potential, and the capacitor 133a (eighth capacitor) electrically connected to another end of the inductor 131a at one end thereof, another end of the capacitor 133a (eighth capacitor) being electrically connected to the reference potential. Because of this, the phase shifting circuit 100 realizes phase shifting using a smaller number of inductors while reducing the loss relating to the phase shifting. This enables the reduction in size of the phase shifting circuit 100.

<4> In the phase shifting circuit according to any one of <1> to <3>, the second phase shifter 130 or 130a of the phase shifting circuit 100 according to an exemplary embodiment of the present disclosure shifts the phase of the signal RF12 (second signal) by the second angle in the direction opposite to the direction of the first angle and outputs the signal RFψ (second output signal), the second angle having an absolute value equal to an absolute value of the first angle. This facilitates the design of the phase shifting circuit 100.

<5> In the phase shifting circuit according to any one of <1> to <4>, the first phase shifter 120 and the second phase shifter 130 of the phase shifting circuit 100 according to an exemplary embodiment of the present disclosure are configured such that the phase difference is 45 degrees. Because of this, the phase shifting circuit 100a realizes phase shifting using a smaller number of inductors without causing an occurrence of the loss relating to the phase shifting. This enables the reduction in size of the phase shifting circuit 100a.

<6> In the phase shifting circuit according to any one of <1> to <5>, the output terminal of the first amplifier 140 of the phase shifting circuit 100 according to an exemplary embodiment of the present disclosure is directly electrically connected to the output terminal of the second amplifier 150. As described above, by directly electrically connecting the output of the first amplifier 140 to the output of the second amplifier 150, the phase shifting circuit 100 can avoid an occurrence of loss caused by the combiner, and this enables the reduction of loss.

<7> In the phase shifting circuit according to any one of <1> to <6>, the dividing circuit 110 of the phase shifting circuit 100 according to an exemplary embodiment of the present disclosure is a 90-degree hybrid coupler. This enables the phase shifting circuit 100 to reduce the loss relating to the phase shifting.

<8> In the phase shifting circuit according to any one of <1> to <6>, the dividing circuit 110 of the phase shifting circuit 100 according to an exemplary embodiment of the present disclosure is a balun. This enables the phase shifting circuit 100 to reduce the loss relating to the phase shifting.

The respective embodiments described above are provided to facilitate understanding of the present disclosure and are not to be construed as limiting the present disclosure. The present disclosure can be modified or improved without departing from its spirit, and the present disclosure also includes equivalents thereof. That is to say, ones obtained by suitably modifying the designs of the respective embodiments by those skilled in the art are also included within the scope of the present disclosure as long as they include the features of the present disclosure. For example, each constituent element included in each embodiment as well as its arrangement, material, condition, shape, size, and the like are not limited to those exemplified, and may be suitably changed. Further, respective constituent elements included in the respective embodiments may be combined as long as technically feasible, and ones obtained by combining those are also included within the scope of the present disclosure as long as they include the features of the present disclosure.

What is claimed is:

1. A phase shifting circuit comprising:
a dividing circuit configured to divide an input signal into a first signal and a second signal, the second signal having a phase different from a phase of the first signal;
a first phase shifter configured to shift the phase of the first signal by a first angle, and to output a first output signal;
a second phase shifter configured to shift the phase of the second signal by a second angle in a direction opposite to a direction of the first angle, and to output a second output signal, a phase difference between the first output signal and the second output signal being greater than 0 degrees and less than 90 degrees;
a first amplifier configured to amplify the first output signal, and to output a first amplified signal; and
a second amplifier configured to amplify the second output signal, and to output a second amplified signal, the second amplifier being connected to the first amplifier such that the first amplified signal and the second amplified signal are combined.

2. The phase shifting circuit according to claim 1,
wherein the first phase shifter comprises:
a first inductor connected in series to the dividing circuit,
a first capacitor, a first end of the first capacitor being electrically connected to a first end of the first inductor, and a second end of the first capacitor being electrically connected to a reference potential, and
a second capacitor, a first end of the second capacitor being electrically connected to a second end of the first inductor, and a second end of the second capacitor being electrically connected to the reference potential, and
wherein the second phase shifter comprises:
a third capacitor connected in series to the dividing circuit,
a fourth capacitor connected in series to the third capacitor, and
a second inductor, a first end of the second inductor being electrically connected to a node between the third capacitor and the fourth capacitor, and a second end of the second inductor being electrically connected to the reference potential.

3. The phase shifting circuit according to claim 1,
wherein the first phase shifter comprises:
a fifth capacitor connected in series to the dividing circuit,
a sixth capacitor connected in series to the fifth capacitor, and
a third inductor, a first end of the third inductor electrically connected to a node between the fifth capacitor and the sixth capacitor, and a second end of the third inductor being electrically connected to a reference potential, and
wherein the second phase shifter comprises:
a fourth inductor connected in series to the dividing circuit,
a seventh capacitor, a first end of the seventh capacitor being electrically connected to a first end of the fourth inductor, and a second end of the seventh capacitor being electrically connected to the reference potential, and
an eighth capacitor, a first end of the eighth capacitor being electrically connected to a second end of the fourth inductor, and a second end of the eighth capacitor being electrically connected to the reference potential.

4. The phase shifting circuit according to claim 1, wherein the second angle has an absolute value equal to an absolute value of the first angle.

5. The phase shifting circuit according to claim 2, wherein the phase difference between the first output signal and the second output signal is 45 degrees.

6. The phase shifting circuit according to claim 3, wherein the phase difference between the first output signal and the second output signal is 45 degrees.

7. The phase shifting circuit according to claim 1, wherein an output terminal of the first amplifier is directly electrically connected to an output terminal of the second amplifier.

8. The phase shifting circuit according to claim 1, wherein the dividing circuit is a 90-degree hybrid coupler.

9. The phase shifting circuit according to claim 1, wherein the dividing circuit is a balun.
